(19) United States
(12) Patent Application Publication
(10) Pub. No.: US 2006/0164002 A1
(43) Pub. Date: Jul. 27, 2006

(54) Laminated polymer with integrated lighting, sensors and electronics

(76) Inventors: Thomas C. O'Brien, Wilmington, DE (US); Marie B. O'Regan, Santa Barbara, CA (US); C. Warren Haas, Wilmington, DE (US)

Correspondence Address: Barbara C Siegell;E I du Pont de Nemours & Company, Legal Patents, Wilmington, DE, 19898, US

(21) Appl. No.: 10/521,501

(22) PCT Filed: Aug. 6, 2003
(86) PCT No.: PCT/US03/24853

§ 371 Date: Jan. 11, 2005

Related U.S. Application Data
(60) Provisional application No. 60/401,257, filed on Aug. 6, 2002.
(60) Provisional application No. 60/462,217, filed on Apr. 11, 2003.

(51) Int. Cl. B32B 27/00; H01L 33/00

(52) U.S. Cl. 313/498; 428/411.1; 428/702

(57) ABSTRACT

This invention relates to laminated polymer as a host for solid state lighting, sensors, energy generation and storage devices and other electronics that are contained within the transparent non-glass interlayers or air cavities of the laminated polymer.

### FIELD OF THE INVENTION

This invention relates to laminated polymer comprised of at least two layers of transparent polymer separated by a transparent non-glass interlayer or an air cavity wherein solid state lighting, sensors, energy generation and storage devices and other electronics are contained within the transparent non-glass interlayer or air cavity.

### TECHNICAL BACKGROUND OF THE INVENTION

Developments being achieved in the fields of solid state lighting, sensors, energy generation and storage devices and other electronics have resulted in products in these areas with reduced imprint and novel features. There is a continual interest in incorporating these developments into structures that are attractive for architectural, automotive and other uses.

An objective of this invention is to use the non-glass interlayer and/or the air cavity in laminated polymer to contain solid state lighting, sensors, energy generation or storage devices and other electronics to enhance the functionality and the aesthetics of the laminated polymer.

### SUMMARY OF THE INVENTION

This invention provides a laminated polymer comprised of at least two layers of transparent polymer with adjacent transparent polymer layers separated by a transparent solid non-glass interlayer or an air cavity, wherein at least one transparent non-glass interlayer or air cavity contains a device comprised of at least one element selected from the group consisting of solid state lighting, heat sensors, light sensors, pressure sensors, thin film capacitance sensors, photovoltaic cells, thin film batteries, liquid crystal display films, suspended particle device films, and transparent electrical conductors.

### DETAILED DESCRIPTION OF THE INVENTION

This invention relates to laminated polymer comprised of transparent polymer layers separated by a transparent solid non-glass interlayer or an air gap and to the utilization of the transparent solid non-glass interlayer or the air cavity between the transparent polymer layers of the laminated polymer for the integration of a broad range of functions that enhance the functionality and the aesthetics of the laminated polymer. The laminated polymer is comprised of at least two layers of transparent polymer with adjacent transparent polymer layers separated by a transparent solid non-glass interlayer or an air cavity. One embodiment of the invention is a laminated polymer comprised of two layers of transparent polymer separated by a transparent solid non-glass interlayer.

The laminated polymer acts as a host that allows digital and thin film technologies to be integrated into or alongside the transparent solid non-glass interlayer or into the air cavity. This allows the transparent solid non-glass interlayer to serve two possible purposes, that of providing mechanical strength to the laminated polymer and that as a host for a device that adds additional functions to the laminated polymer. Similarly, it allows the air cavity to serve two purposes, that of thermal insulator and that as a host for a device that adds additional functions to the laminated polymer. As used herein, “transparent”, when used in connection with transparent polymer layer or transparent solid non-glass interlayer, means a polymer layer or a solid non-glass interlayer which transmits light with no appreciable scattering as well as a polymer layer or a solid non-glass interlayer which is translucent, i.e., which partially transmits light. The degree of transparency required of the transparent polymer layer or transparent solid non-glass interlayer will usually be dictated by how the laminate is to be used. If the use requires as completely transparent a laminate as possible, e.g., for use as a window, the transparent polymer layer and transparent solid non-glass interlayer should transmit light with no appreciable scattering. For other uses, a transparent polymer layer and a transparent solid non-glass interlayer that partially transmit light can be quite acceptable.

The invention provides that at least one transparent solid non-glass interlayer or air cavity contain a device comprised of at least one element selected from the group consisting of solid state lighting, heat sensors, light sensors, pressure sensors, thin film capacitance sensors, photovoltaic cells, thin film batteries, liquid crystal display films, suspended particle device films, and transparent electrical conductors. When a transparent solid non-glass interlayer is used, the interlayer may be perforated to provide space for the elements of the device. Such perforations can also serve as light scattering centers when the source of light is placed along the edge of the transparent solid non-glass interlayer. Alternatively, the elements of the device may be adjacent to the transparent solid non-glass interlayer. Preferred as the transparent solid non-glass interlayer is a Butacite® PVB (polyvinyl butyral) interlayer available from E. I. du Pont de Nemours and Company, Wilmington, Del. Transparent electrical conductors such as indium tin oxide can be deposited directly onto the transparent polymer.

The solid state lighting can be in the form of light-emitting diodes (LEDs), an optoelectrical device consisting of a p-n junction that emits light (ultraviolet, visible or infrared radiation) in response to a forward current passing through the diode. LEDs are made using inorganic materials. The solid state lighting can also be in the form of organic light-emitting diodes (OLEDs). The OLEDS can polymeric light-emitting diodes (pLEDs) or small molecule organic light-emitting diodes (SMOLEDs). Transparent electrical conductors can be used to provide means to apply an activating voltage to the individual LEDs or OLEDs. Indium tin oxide is a preferred transparent electrical conductor. The source of illumination can also be in the form of an electroluminescent (EL) film. When the source of light is placed along the edge of the transparent solid non-glass interlayer it can be used to enhance images printed on the transparent solid non-glass interlayer. A microprocessor chip to control the solid state lighting can be provided either as part of the device contained in at least one transparent solid non-glass interlayer or air cavity or can be provided externally to the laminated polymer. The microprocessor chip can be programmed to cause the solid lighting to display a sequence of images. The images can be in the form of a pictorial or aesthetic display or text. Motion detectors can be used to detect motion and the image changed accordingly. For example, when a thin film capacitance sensor is made part of the device, the motion of an object, such as a hand, can change the display. Alternatively, a pressure sensor can detect the application of pressure to the surface of the laminated polymer and provide a change in the display. The laminated polymer remains transparent over the parts of the laminated polymer where there is no solid state lighting or where the solid state lighting is not activated. The portion of the laminated polymer where the solid state lighting is activated displays images and information such as temperature, time, stock prices, etc. as well as programmable text and messages.

When the polymer layers are sufficiently thin, the laminated polymer will be flexible and can be adapted to various shapes and forms. Such a flexible laminated polymer is especially useful when curved or other non-flat displays are desired. Depending on the degree of flexibility, the flexible laminated polymer may need to be attached to a support having the desired shape. Alternatively, the flexible laminated polymer can be contained within a glass support. When OLEDs are used as the source of illumination, the glass container would also provide a moisture and oxygen barrier for the OLEDs and thereby improve the OLED lifetime.

As the polymer thickness increases and the mechanical strength of the laminated polymer increases the laminated polymer is conformable to various shapes and forms.

When the polymer layers are sufficiently thick to provide mechanical strength and stability to the laminated polymer structure, the laminated polymer can serve as an external or internal window, as an external or internal wall or surface, or as a display surface.

Another device that can be incorporated in the transparent non-glass interlayer is one that converts energy received in the form of light from the sun or other light sources into electrical energy that can be stored in a battery and used to power LEDs, OLEDs, electroluminescent films, liquid crystal display films, electrochromic suspended particle device films, etc. For example, the device can be comprised of a thin film photovoltaic panel, a rechargeable thin film lithium battery and transparent indium tin oxide films to conduct electricity between the various elements. Alternatively, the battery could be used to power another device not within the window. With the addition of a microprocessor to control the illumination, the energy stored in the battery can be used to provide different types of displays in the window during different times of the day. For example, the display could supply information, advertising, etc. during daylight hours; it could supply illumination during the evening hours; it could act as a night-light. Since the lithium battery is opaque and typical reasonably priced photovoltaic cells are opaque, these elements are localized in one portion area of the transparent non-glass interlayer. This device comprised of a thin film photovoltaic panel and a rechargeable thin film lithium battery can also be used in other embodiments of the laminated polymer.

The embodiment of the invention of a laminated polymer comprised of two layers of transparent polymer separated by a transparent solid non-glass interlayer, i.e., polymer-interlayer-polymer, or a laminated polymer comprised of three layers of transparent polymer and two transparent solid non-glass interlayers, i.e., polymer-interlayer-polymer-interlayer-polymer, are particularly useful for illumination or displays and especially for providing a flexible laminated polymer for these uses. The transparent solid non-glass interlayer can be illuminated by LEDs or OLEDs in the transparent solid non-glass interlayer or by LEDs or OLEDs positioned at the edges of the transparent solid non-glass interlayer. The laminated polymer comprised of three layers of transparent polymer and two transparent solid non-glass interlayers provides with each transparent solid non-glass interlayer containing a lighting device provides an even wider variety of lighting variations than the laminated polymer comprised of two layers of transparent polymer separated by a transparent solid non-glass interlayer. With two lighting devices within the laminated polymer, various combinations of lighting can be obtained.

### EXAMPLE OF THE INVENTION

This Example demonstrates the use of a flexible laminated polymer of the invention as a source of illumination. The flexible laminated polymer containing a PLED lighting device was fabricated in the following manner. A flexible substrate of poly(ethylene terephthalate) (PET) sheet was partially coated with an indium tin oxide (ITO) film to serve as the anode of the device. A poly(3,4-ethylenedioxythiophene) (PEDOT) blend, CH8000 (commercially available from Bayer AG, Germany) was spin-coated at 1,000 rpm for 80 seconds, in air, onto the ITO-coated PET. The resulting film was dried on a hot plate at 120° C. for 1 minute and then overnight under vacuum at 90° C. A solution of a yellow emitter PDY®32 (commercially available as a pre-made solution from Covion Organic Semiconductors, GmbH, Frankfurt, Germany) was spin-coated at 330 rpm for 30 seconds, followed by 1000 rpm for 20 seconds, onto the PEDOT thin film. The PEDOT and PDY®132 were removed in the areas where the cathode and anode must make contact with the current source. A low work function metal, Ca, was vapor deposited on the film of PEDOT and PDY®32 to a thickness of 10 to 30 nm. A layer of aluminum was vapor deposited on top of the Ca layer to a thickness of 300 nm to complete the cathode formation. A layer of uv-curable epoxy was spread over the device, but leaving the contact area uncovered. A piece of poly(ethylene terephthalate) (PET) sheet was placed on top of the epoxy, and the epoxy was cured with uv light. When a battery was connected to the electrodes, the entire device emitted yellow light.

What is claimed is:

1. A laminated polymer comprised of at least two layers of transparent polymer with adjacent polymer layers separated by a transparent solid non-glass interlayer or an air cavity, wherein at least one said transparent non-glass interlayer or said air cavity contains a device comprised of at least one element selected from the group consisting of solid state lighting, heat sensors, light sensors, pressure sensors, thin film capacitance sensors, photovoltaic cells, thin film batteries, liquid crystal display films, suspended particle device films, and transparent electrical conductors.

2. The laminated polymer of claim 1, comprised of two layers of transparent polymer separated by a transparent solid non-glass interlayer.

3. The laminated polymer of claims 1 or 2, wherein said device is comprised of solid state lighting.

4. The laminated polymer of claim 3, wherein said solid state lighting is in the form of at least one light emitting diode.

5. The laminated polymer of claim 3, wherein said solid state lighting is in the form of at least one organic light emitting diode.

6. The laminated polymer of claim 3, wherein said solid state lighting is in the form of an electroluminescent film.

7. The laminated polymer of claim 3, wherein said device is further comprised of transparent electrical conductors to provide means to apply an activating voltage to said solid state lighting.

8. The laminated polymer of claim 7, wherein said transparent electrical conductors are indium tin oxide films.

9. The laminated polymer of claim 7, wherein said device is further comprised of a microprocessor chip that is programmed to control said solid state lighting and to cause said solid state lighting to display a sequence of images.

10. The laminated polymer of claim 9, wherein said microprocessor chip is programmed to cause said solid state lighting to display text.

11. The laminated polymer of claim 7, wherein there is provided externally to said laminated polymer a microprocessor chip that is programmed to control said solid state lighting and to cause said solid state lighting to display a sequence of images.

12. The laminated polymer of claim 11, wherein said microprocessor chip is programmed to cause said solid state lighting to display text.

13. The laminated polymer of claim 3, wherein the laminated polymer is flexible and can be adapted to various shapes and forms.

14. The laminated polymer of claim 13, wherein said solid state lighting is in the form of at least one light emitting diode.

15. The laminated polymer of claim 13, wherein said solid state lighting is in the form of at least one organic light emitting diode.
